(19) United States
(12) Patent Application Publication
(10) Pub. No.: US 2026/0150376 A1
(43) Pub. Date: May 28, 2026

(54) SEMICONDUCTOR DEVICE

(71) Applicant: HON HAI PRECISION INDUSTRY CO., LTD., New Taipei City (TW)

(72) Inventors: Wen-Yuan HSIEH, New Taipei City (TW); Jheng-Sheng YOU, Hsinchu City (TW); Hung-Yu CHEN, New Taipei City (TW)

(21) Appl. No.: 19/026,521

(22) Filed: Jan. 17, 2025

(30) Foreign Application Priority Data
Nov. 22, 2024 (TW) 113145079

(51) Int. Cl. H10D 64/62; H10D 30/47; H10D 62/824; H10D 62/85; H10D 62/852

(52) U.S. Cl. CPC H10D 64/62; H10D 30/475; H10D 62/824; H10D 62/8503; H10D 62/852

(57) ABSTRACT

Some embodiments of the present disclosure provide a semiconductor device including a contact electrically connected to an III-V semiconductor bulk layer. A metal layer stack of the contact includes metal layers and a metal nitride capping layer at the topmost layer of the metal layer stack. The metal layers include a metal bottom layer having a metal element at the bottommost layer of the metal layer stack, where the metal nitride capping layer has a nitride of the metal element. A thickness of the metal bottom layer is larger than a thickness of the metal nitride capping layer.

### CROSS-REFERENCE TO RELATED APPLICATION

This application claims priority to Taiwan Application Serial Number 113145079, filed Nov. 22, 2024, which is herein incorporated by reference in its entirety.

### BACKGROUND

### Field of Invention

The present disclosure relates to the semiconductor device. More particularly, the present disclosure relates to the III-V semiconductor device.

### Description of Related Art

For semiconductor devices requiring high energy conversion efficiency, high data transfer rate, and low energy consumption, the III-V semiconductor materials, such as gallium nitride, has several characteristics which makes it suitable to be applied in such semiconductor devices, for example, wide band gap, high breakdown voltage, high electron saturation velocity, and high thermal stability. However, the III-V semiconductor materials may cause the high stress in the semiconductor device. This could easily lead to the defect of material cracking of the components in the device.

### SUMMARY

According to some embodiments of the present disclosure, a semiconductor device includes a contact electrically connected to an III-V semiconductor bulk layer. A metal layer stack of the contact includes metal layers and a metal nitride capping layer at a topmost layer of the metal layer stack, where the metal layers include a metal bottom layer at a bottommost layer of the metal layer stack. The metal bottom layer has a metal element, and the metal nitride capping layer has a nitride of the metal element. A thickness of the metal bottom layer is larger than a thickness of the metal nitride capping layer.

According to some embodiments of the present disclosure, a semiconductor device includes a bulk layer, a gate structure on the bulk layer, and a contact that is on the bulk layer and adjacent to the gate structure. The bulk layer includes at least a layer of an III-V semiconductor material and provides a compressive stress, where the contact provides a tensile stress. The contact includes a stack of metal layers and a metal nitride capping layer above the metal layers, where a thickness of a bottommost layer of the metal layers is larger than a thickness of the metal nitride capping layer.

According to the above-mentioned embodiments, the semiconductor device of the present disclosure includes a contact electrically connected to an III-V semiconductor bulk layer, where the contact includes a metal bottom layer at the bottommost layer of a stack and a metal nitride capping layer at the topmost layer of the stack. A thickness of the metal bottom layer is larger than a thickness of the metal nitride capping layer to balance the compressive stress of the bulk layer by the tensile stress of the contact. Therefore, the risk of cracking the material in the semiconductor device may be reduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device, according to one embodiment of the present disclosure.

FIGS. 2-4 illustrate schematic cross-sectional views of contacts, according to some embodiments of the present disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the present disclosure provide a semiconductor device including a contact electrically connected to an III-V semiconductor bulk layer. A layer stack of the contact includes a metal bottom layer at the bottommost layer and a metal nitride capping layer at the topmost layer, and a thickness of the metal bottom layer is larger than a thickness of the metal nitride capping layer. As a result, the contact may release the total stress in the semiconductor device, thereby reducing the risk of cracking material and improving the fabrication yield of the semiconductor device.

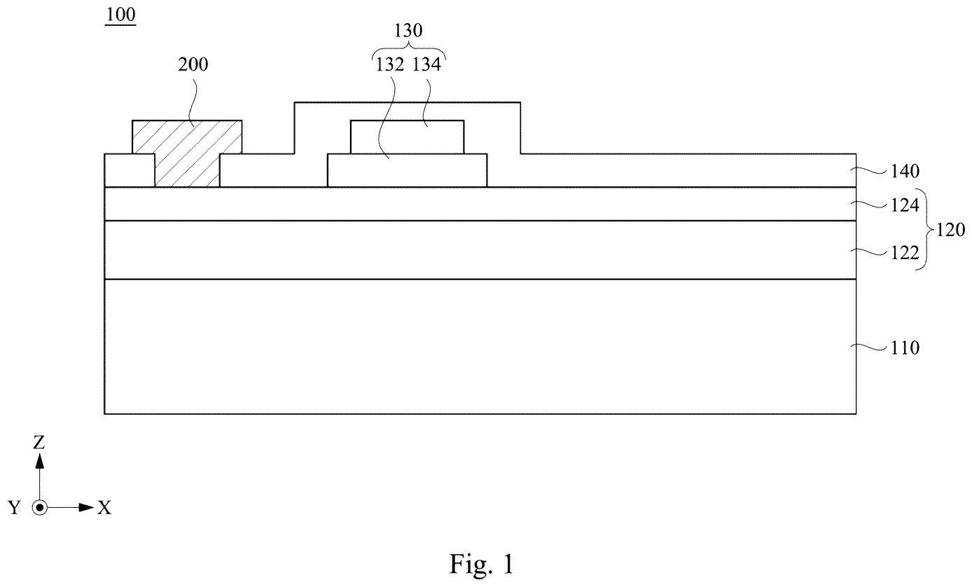

According to one embodiment of the present disclosure, FIG. 1 illustrates a cross-sectional view of a semiconductor device 100. The semiconductor device 100 includes a substrate 110, a bulk layer 120 on the substrate 110, a gate structure 130 on the bulk layer 120, and a contact 200 that is on the bulk layer 120 and adjacent to the gate structure 130. Specifically, the substrate 110 may include an elemental semiconductor, a compound semiconductor, or a base material suitable for the semiconductor device 100, such as silicon, silicon carbide, silicon germanium, or the like. The substrate 110 may be made of un-doped semiconductor material or doped semiconductor material, where the dopant may be, for example, nitrogen (N), phosphorous (P), arsenic (As) or other n-type dopant, or boron (B), gallium (Ga) or other p-type dopant.

The bulk layer 120 includes at least a layer of III-V semiconductor material as a channel layer of the semiconductor device 100. The III-V semiconductor material of the bulk layer 120 may be a compound semiconductor having at least a III-group element and at least a V-group element, including but not limited to gallium nitride (GaN), gallium arsenide (GaAs), aluminum gallium nitride (AlGaN), indium gallium nitride (InGaN), or the like. For example, the bulk layer 120 may include a gallium nitride layer 122 and an aluminum gallium nitride layer 124 on the gallium nitride layer 122. An interface formed by the directly contacted gallium nitride layer 122 and aluminum gallium nitride layer 124 may become a two-dimensional electron gas (2DEG) structure with high concentration of charge carriers, so that the semiconductor device 100 has a high electron mobility. Such semiconductor device 100 may be referred to as a high electron mobility transistor (HEMT).

The gate structure 130, as an enhanced mode gate, may include a doped III-V semiconductor material to control the current flow in the bulk layer 120. For example, the gate structure 130 may include a p-type gallium nitride (p-GaN) layer 132 and a capping layer 134 on the p-type gallium nitride layer 132, where the capping layer 134 may be made of titanium nitride (TiN). In some embodiments, the gate structure 130 may also include a gate dielectric layer (not shown), such as an oxide silicon layer, a metal oxide layer, or the like, between the p-type gallium nitride layer 132 and the bulk layer 120. In some embodiments, the semiconductor device 100 may also include a protective layer 140 on the bulk layer 120 and the gate structure 130. The protective layer 140 covers the top surface of the bulk layer 120, the top surface of the gate structure 130, and the sidewalls of the gate structure 130 to reduce the risk of damaging the bulk layer 120 and the gate structure 130 by abrasion, erosion, or contamination.

The contact 200 is positioned on one side of the gate structure 130 and electrically connected to the bulk layer 120. When the protective layer 140 exists in the semiconductor device 100, the contact 200 may extend through the protective layer 140 to contact the top surface of the bulk layer 120, for example, the aluminum gallium nitride layer 124 in FIG. 1. The contact 200 may be a source/drain contact of the semiconductor device 100, but the present disclosure is not limited thereto. The contact 200 includes an appropriate metal layer stack, so that the contact resistance between the contact 200 and the bulk layer 120 is small enough to call the contact 200 as an Ohmic contact of the semiconductor device 100.

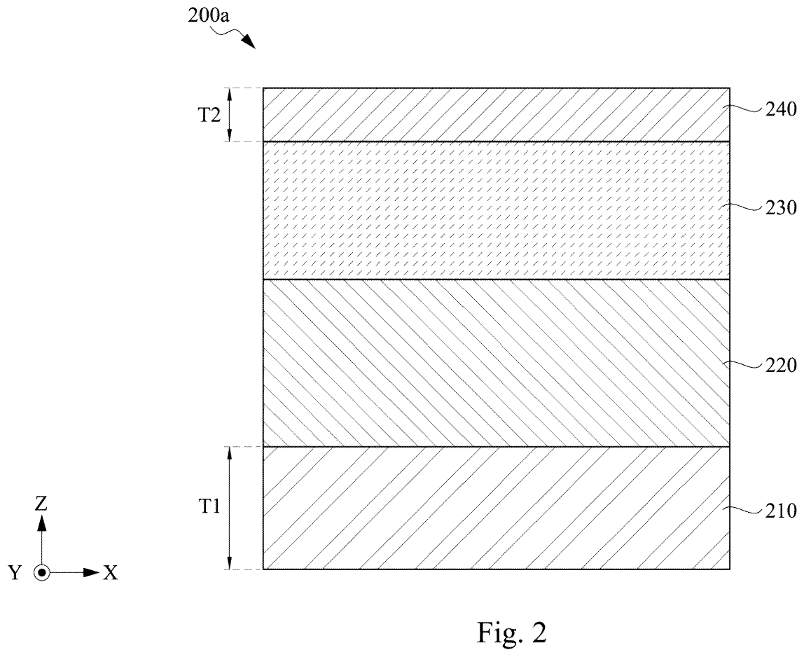

To discuss the contact 200 in further details, FIG. 2 illustrates a schematic cross-sectional view of a contact 200a, according to one embodiment of the present disclosure. The material stack of the contact 200a in FIG. 2 may be used in the contact 200 in FIG. 1. In other words, the material stack illustrated in FIG. 2 may be a partial cross-sectional view of the contact 200.

The contact 200a includes a metal bottom layer 210 at the bottommost layer, a first metal layer 220 on the metal bottom layer 210, a second metal layer 230 on the first metal layer 220, and a metal nitride capping layer 240 on the second metal layer 230. The metal bottom layer 210 to the metal nitride capping layer 240 may be sequentially deposited by using, for example, physical vapor deposition (PVD), chemical vapor deposition (CVD), sputtering, or other suitable techniques to form the metal layer stack of the contact 200a.

Any adjacent two of the metal bottom layer 210, the first metal layer 220, and the second metal layer 230 may be made of different metal materials to reduce the contact resistance between the contact 200a and the III-V semiconductor material. For example, the metal bottom layer 210 may be a titanium (Ti) metal layer, the first metal layer 220 may be an aluminum (Al) metal layer, and the second metal layer 230 may be a titanium metal layer. The contact 200a illustrated in FIG. 2 includes two additional metal layers (i.e., the first metal layer 220 and the second metal layer 230) between the metal bottom layer 210 and the metal nitride capping layer 240. In some other embodiments, less than or more than two additional metal layers may exist between the metal bottom layer 210 and the metal nitride capping layer 240, and the additional metal layer may include other metal-including materials. For example, the first metal layer 220 may be an aluminum metal layer doped with non-metal element, or the second metal layer 230 may be a nickel (Ni) metal layer.

The metal nitride capping layer 240 at the topmost layer of the contact 200a may protect the other material layers in the contact 200a. The metal nitride capping layer 240 may include the nitride of titanium (Ti), zirconium (Zr), niobium (Nb) (Nb), tantalum (Ta), molybdenum (Mo), tungsten (W), other metals, or combinations thereof. For example, the metal nitride capping layer 240 may be a titanium nitride (TiN) layer. In such embodiments, the metal bottom layer 210 and the metal nitride capping layer 240 may have the same metal element, i.e., the metal bottom layer 210 is made of a metal element while the metal nitride capping layer 240 is made of a nitride of the same metal element.

It should be noted that, as shown in FIG. 2, a thickness T1 of the metal bottom layer 210 is larger than a thickness T2 of the metal nitride capping layer 240 in the Z-axis direction. In other words, during the material deposition of the contact 200a, the deposited thickness T1 of the metal bottom layer 210 is larger than the deposited thickness T2 of the metal nitride capping layer 240. The thickness difference between the metal bottom layer 210 and the metal nitride capping layer 240 can adjust the stress of the contact 200a, thereby reducing the defect in the semiconductor device and improving the stability of the semiconductor device.

More specifically, the bulk layer, such as the bulk layer 120 in FIG. 1, including the III-V semiconductor material generally provides a compressive stress. As the thickness of the metal bottom layer 210 being larger than that of the metal nitride capping layer 240 in the contact 200a, the contact 200a tends to provide a tensile stress that may lower the compressive stress of the bulk layer. In other words, the contact 200a may release the total stress in the semiconductor device, thereby reducing the risk of material cracking of the components in the semiconductor device and improving the fabrication yield of the semiconductor device. Additionally, the thicker metal bottom layer 210 may also enhance the adhesion between the contact 200a and the bulk layer, which improves the structure stability of the semiconductor device. In some embodiments, a ratio between the thickness T1 of the metal bottom layer 210 and the thickness T2 of the metal nitride capping layer 240 (T1:T2) may be between 1:1 and 20:1 to release the total stress in the semiconductor device. If the ratio between the thickness T1 and thickness T2 is smaller than 1:1, the tensile stress of the contact 200a may be too high to release the total stress. If the ratio between the thickness T1 and the thickness T2 is larger than 20:1, the stress in the semiconductor device may not be well released, leading to the component cracking in the semiconductor device.

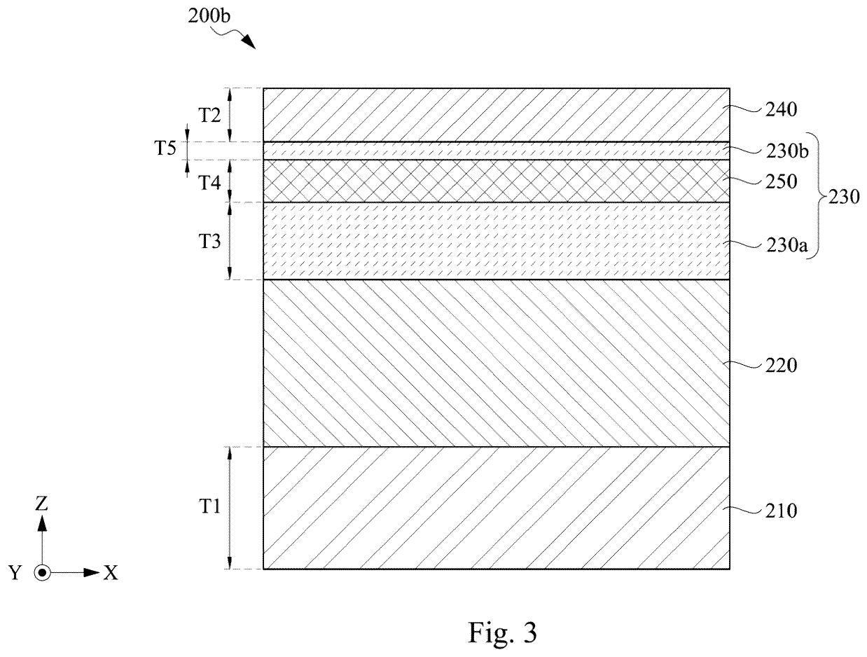

According to another embodiment of the present disclosure, FIG. 3 illustrates a schematic cross-sectional view of a contact 200b. The contact 200b is similar to the contact 200a in FIG. 2, but the second metal layer 230 in the contact 200b includes multiple second metal sub-layers and an interlayer metal nitride layer. Specifically, the contact 200b includes a metal bottom layer 210 having a thickness T1, a metal nitride capping layer 240 having a thickness T2 smaller than the thickness T1, and a first metal layer 220 and a second metal layer 230 between the metal bottom layer 210 and the metal nitride capping layer 240. The second metal layer 230 includes a second metal sub-layer 230a, a second metal sub-layer 230b, and an interlayer metal nitride layer 250 between the second metal sub-layer 230a and the second metal sub-layer 230b. In other words, the interlayer metal nitride layer 250 is interposed between the second metal sub-layer 230a and the second metal sub-layer 230b and separates the two second metal sub-layers.

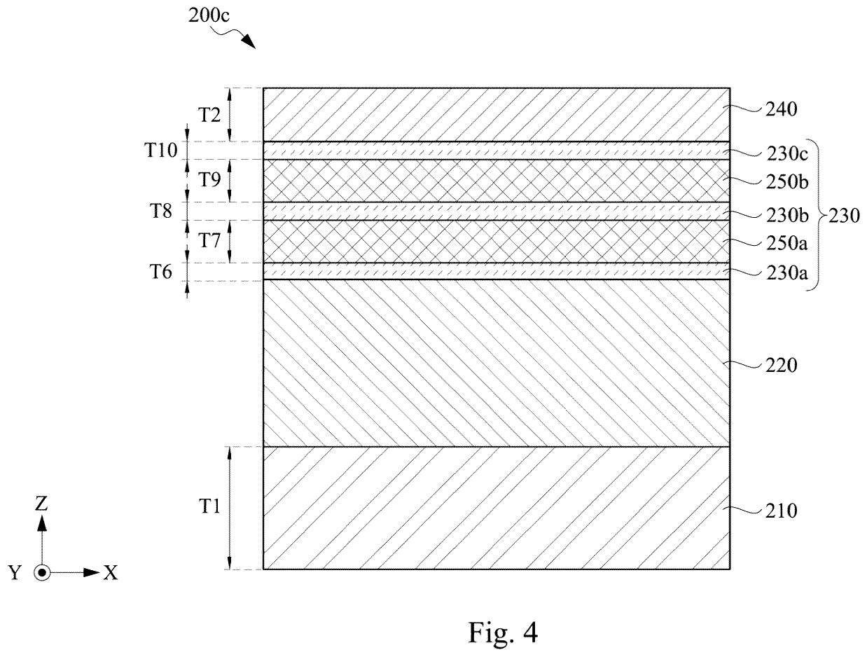

According to another embodiment of the present disclosure, FIG. 4 illustrates a schematic cross-sectional view of a contact 200c. The contact 200c is similar to the contact 200b, but the contact 200c has multiple second metal sub-layers and multiple interlayer metal nitride layers. Specifically, the contact 200c includes a metal bottom layer 210 having a thickness T1, a metal nitride capping layer 240 having a thickness T2 smaller than the thickness T1, and a first metal layer 220 and a second metal layer 230 between the metal bottom layer 210 and the metal nitride capping layer 240. The second metal layer 230 includes a second metal sub-layer 230a, a second metal sub-layer 230b, a second metal sub-layer 230c, an interlayer metal nitride layer 250a between the second metal sub-layer 230a and the second metal sub-layer 230b, and an interlayer metal nitride layer 250 b between the second metal sub-layer 230b and the second metal sub-layer 230c. In other words, the interlayer metal nitride layer 250 a is interposed between the second metal sub-layer 230a and the second metal sub-layer 230b while the interlayer metal nitride layer 250b is interposed between the second metal sub-layer 230b and the second metal sub-layer 230c, thereby separating the three second metal sub-layers from each other.

In FIG. 3 and FIG. 4, the second metal layer 230 has multiple second metal sub-layers and at least one interlayer metal nitride layer, where the second metal sub-layers and the interlayer metal nitride layer are alternately stacked to form a composite layer. Such composite layer may easily adjust the stress of the contact 200b and the contact 200c to meet the requirements. In some embodiments, the second metal sub-layers in the second metal layer 230 may have a same material. Taking FIG. 3 as an example, the second metal sub-layer 230a and the second metal sub-layer 230b may both be a titanium metal layer. The interlayer metal nitride layer 250 of the second metal layer 230 may be a metal nitride layer having a single metal element or an alloy nitride layer having multiple metal elements, where the one or more metal elements may be selected from a group consisting of titanium (Ti), tantalum (Ta), tungsten (W), zinc (Zn), zirconium (Zr), strontium (Sr), tin (Sn), nickel (Ni), scandium (Sc), vanadium (V), chromium (Cr), manganese (Mn), molybdenum (Mo), niobium (Nb), rhenium (Re), aluminum (Al), gallium (Ga), indium (In), lithium (Li), magnesium (Mg), tellurium (Te), yttrium (Y), hafnium (Hf), ruthenium (Ru), rhodium (Rh), osmium (Os), iridium (Ir), technetium (Tc), dubnium (Db), seaborgium (Sg), bohrium (Bh), rutherfordium (Rf), and cerium (Ce).

In some embodiments, a total thickness of the second metal sub-layers of the second metal layer 230 may be between 5 nm and 100 nm, and a total thickness of the interlayer metal nitride layers may be between 5 nm and 200 nm. This allows the brittleness and the mechanical strength of the contact to be adjusted by the second metal layer 230 and the adjacent first metal layer 220 for matching with the material layers other than the contact itself.

As shown in FIG. 3, in the Z-axis direction, the second metal sub-layer 230a has a thickness T3, the interlayer metal nitride layer 250 has a thickness T4, and the second metal sub-layer 230b has a thickness T5. When the sum of the thickness T3 and the thickness T5 is between 5 nm and 100 nm, and the thickness T4 is between 5 nm and 200 nm, the brittleness and the mechanical strength of the second metal layer 230 may be improved. Similarly, as shown in FIG. 4, in the Z-axis direction, the second metal sub-layer 230a has a thickness T6, the interlayer metal nitride layer 250a has a thickness T7, the second metal sub-layer 230b has a thickness T8, the interlayer metal nitride layer 250b has a thickness T9, and the second metal sub-layer 230c has a thickness T10. The sum of the thickness T6, thickness T8, and thickness T10 is between 5 nm and 100 nm, while the sum of the thickness T7 and the thickness T9 is between 5 nm and 200 nm.

According to the above-mentioned embodiments, the semiconductor device of the present disclosure includes the contact electrically connected to the III-V semiconductor bulk layer, where the contact includes a stack of multiple metal layers to become the Ohmic contact of the semiconductor device. The metal layer stack of the contact includes a metal bottom layer at the bottommost layer and a metal nitride capping layer at the topmost layer. The thickness of the metal bottom layer is larger than the thickness of the metal nitride capping layer to balance the compressive stress of the bulk layer by the tensile stress of the contact, thereby reducing the risk of material cracking and enhancing the adhesion between the components. The metal layer stack may further includes the composite layer formed by the metal sub-layers and the interlayer metal nitride layer, which adjusts the stress, brittleness, and mechanical strength of the contact corresponding to the material layers other than the contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a contact electrically connected to a III-V semiconductor bulk layer, wherein a metal layer stack of the contact comprises:
metal layers including a metal bottom layer at a bottommost layer of the metal layer stack, wherein the metal bottom layer has a metal element; and
a metal nitride capping layer at a topmost layer of the metal layer stack, wherein the metal nitride capping layer has a nitride of the metal element, and
wherein a thickness of the metal bottom layer is larger than a thickness of the metal nitride capping layer.

2. The semiconductor device of claim 1, wherein a ratio between the thickness of the metal bottom layer and the thickness of the metal nitride capping layer is between 1:1 and 20:1.

3. The semiconductor device of claim 1, further comprising:
a first metal layer between the metal bottom layer and the metal nitride capping layer; and
a second metal layer between the first metal layer and the metal nitride capping layer,
wherein any adjacent two of the metal bottom layer, the first metal layer, and the second metal layer have different metal materials.

4. The semiconductor device of claim 3, wherein the metal bottom layer is a titanium metal layer, the first metal layer is an aluminum metal layer, and the second metal layer is a titanium metal layer.

5. The semiconductor device of claim 3, wherein the second metal layer includes second metal sub-layers and at least one interlayer metal nitride layer, and the at least one interlayer metal nitride layer separates the second metal sub-layers.

6. The semiconductor device of claim 5, wherein a total thickness of the second metal sub-layers is between 5 nm and 100 nm, and a total thickness of the at least one interlayer metal nitride layer is between 5 nm and 200 nm.

7. The semiconductor device of claim 5, wherein a metal element of the at least one interlayer metal nitride layer is selected from a group consisting of titanium (Ti), tantalum (Ta), tungsten (W), zinc (Zn), zirconium (Zr), strontium (Sr), tin (Sn), nickel (Ni), scandium (Sc), vanadium (V), chromium (Cr), manganese (Mn), molybdenum (Mo), niobium (Nb), rhenium (Re), aluminum (Al), gallium (Ga), indium (In), lithium (Li), magnesium (Mg), tellurium (Te), yttrium (Y), hafnium (Hf), ruthenium (Ru), rhodium (Rh), osmium (Os), iridium (Ir), technetium (Tc), dubnium (Db), seaborgium (Sg), bohrium (Bh), rutherfordium (Rf), and cerium (Ce).

8. A semiconductor device, comprising:
a bulk layer including at least a layer of a III-V semiconductor material, wherein the bulk layer provides a compressive stress;
a gate structure on the bulk layer; and
a contact on the bulk layer and adjacent to the gate structure, wherein the contact provides a tensile stress, and
wherein the contact includes a stack of metal layers and a metal nitride capping layer above the metal layers, and a thickness of a bottommost layer of the metal layers is larger than a thickness of the metal nitride capping layer.

9. The semiconductor device of claim 8, wherein the bulk layer comprises:
a gallium nitride layer; and
an aluminum gallium nitride layer on and directly contacts the gallium nitride layer, wherein the bottommost layer of the metal layers directly contacts the aluminum gallium nitride layer.

10. The semiconductor device of claim 8, wherein the contact is an Ohmic contact of the semiconductor device.
